(19) United States
(12) Patent Application Publication
(10) Pub. No.: US 2010/0208186 A1
(43) Pub. Date: Aug. 19, 2010

(54) DISPLAY DEVICE AND MANUFACTURING MEHTOD THEREOF

(75) Inventors: Hideo TANABE, Mobara (JP); Toshio Tojo, Ichinomiya (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi Displays, Ltd.

(21) Appl. No.: 12/700,763

(22) Filed: Feb. 5, 2010

(30) Foreign Application Priority Data
Feb. 18, 2009 (JP) 2009-034817

(51) Int. Cl. G02F 1/1343; G03F 7/20; H01L 21/77

(52) U.S. Cl. 349/139; 430/319; 438/30; 257/E21.535

(57) ABSTRACT

In a manufacturing method of a display device where a photosensitive material film formed on a light-transmitting film is divided into a plurality of small regions and the respective small regions of the photosensitive material film are sequentially exposed, it is possible to decrease the deviation of a focal point of light to be radiated to each small region. In exposing the photosensitive material film formed on the light-transmitting film, the whole exposure subject region of the photosensitive material film is divided into a plurality of small regions, and a focal point of light to be radiated to each small region is decided. The focal point of the light is decided such that the whole exposure subject region of the photosensitive material film is divided into a plurality of length measurement unit regions, and the focal point is determined based on a distance from an optical system of an exposure device to the photosensitive material film which is measured for every length measurement unit region, and an opaque conductive layer is formed in each length measurement unit region prior to the formation of the light-transmitting film.

### CLAIM OF PRIORITY

The present application claims priority from Japanese application serial No. 2009-34817, filed on Feb. 18, 2009, the content of which is hereby incorporated by reference into this application.

### BACKGROUND OF THE INVENTION

1. Field of the Invention

The present invention relates to a manufacturing method of a display device and the display device, and more particularly to a technique which is effectively applicable to a manufacturing method which includes a step of exposing and developing a photosensitive material film formed on a light-transmitting film.

2. Description of the Related Art

Conventionally, as a manufacturing method of a liquid crystal display panel, there has been known a so-called multiple-piece collective manufacturing in which a plurality of liquid crystal display panels are collectively manufactured using a pair of substrates (mother glasses).

In manufacturing the liquid crystal display panels by multiple-piece collective manufacturing, firstly, in each of a plurality of circuit forming regions on one of the pair of substrates, a plurality of lines constituted of a plurality of scanning signal lines and a plurality of video signal lines, a plurality of TFT elements, a plurality of transparent electrodes, an alignment film and the like are formed. Further, on the other of the pair of substrates, a black matrix, color filters, an alignment film and the like are formed in a region corresponding to the circuit forming region.

These two substrates are adhered to each other, a liquid crystal material is sealed in a space defined between these two substrates, and the pair of substrates are cut along the respective circuit forming regions thus dividing the pair of substrates into a plurality of liquid crystal display panels.

In forming the scanning signal lines, the video signal lines, the TFT elements and the transparent electrodes on the substrate, in general, the scanning signal lines, the video signal lines and the TFT elements are formed and, thereafter, the transparent electrodes which are connected to sources or drains of the TFT elements (hereinafter referred to as pixel electrodes) are formed. Here, the scanning signal lines, the video signal lines and the like are formed by etching a conductive film such as an aluminum film (Al film), for example. Semiconductor layers of the TFT elements are formed by etching a semiconductor film made of amorphous silicon or polycrystalline silicon, for example. Further, the pixel electrodes are formed by etching a light-transmitting conductive film such as an ITO film, for example.

In etching the conductive film or the semiconductor film, a photosensitive material film is formed on the conductive film or the semiconductor film to be etched, and the photosensitive material film is exposed and developed thus forming an etching mask.

The exposure of the photosensitive material film is conventionally performed using an exposure device which uses a photo mask (reticle) in general. In exposing the photosensitive material film using the exposure device which uses the photo mask, for example, the whole exposure subject region may be exposed at a time, or the exposure subject region may be divided into a plurality of small regions and the respective small regions may be sequentially exposed.

However, the partial correction of the photo mask is substantially impossible. Accordingly, when a defect in shape occurs in a pattern obtained by exposing and developing the photosensitive material film, or in a conductive film formed by etching using the pattern as a mask or the like, there arises a drawback that it is necessary to form a new photo mask, for example.

Accordingly, recently, there has been proposed a manufacturing method of a liquid crystal display panel in which a photosensitive material film is exposed using an exposure device which does not require a photo mask such as an exposure device referred to as a direct exposure machine, for example.

The direct exposure machine is an exposure device which includes MEMS (Micro Electro Mechanical Systems) which are referred to as a DMD (Digital Mirror Device) or a GLV (Grating Light Valve), for example, and controls a pattern of a radiation light by a numerical control based on layout data prepared by a CAD or the like (see JP-A-62-021220 (patent document 1), JP-A-2003-332221 (patent document 2), JP-A-2002-139845 (patent document 3), for example). Accordingly, when a defect in shape occurs in a pattern obtained by exposing and developing a photosensitive material film, a conductive film formed by etching using the pattern as a mask or the like, it is sufficient to correct numerical values corresponding to a portion where the defect in shape occurs. Accordingly, the method which exposes the photosensitive material film using the direct exposure machine has been attracting an attention as one of methods which can reduce irregularities in display characteristics and a manufacturing cost of a high-definition liquid crystal display panel.

### SUMMARY OF THE INVENTION

A substrate which is used for manufacturing liquid crystal display panels by a multiple-piece collective manufacturing has a large area, and has surface irregularities on a surface where scanning signal lines and the like are formed, for example. Accordingly, when an exposure subject region is divided into a plurality of small regions, and the respective small regions are sequentially exposed in the exposure of the photosensitive material film, a distance between an optical system of an exposure device and the photosensitive material film differs among the respective small regions.

In a conventional exposure device which uses a photo mask, a focal depth of an optical system is usually deeper than a fluctuation amount of a distance between an optical system and a photosensitive material film in respective small regions. Accordingly, in such an exposure device which uses the photo mask, an exposure defect caused by surface irregularities of a substrate hardly occurs. For example, an exposure defect that an unexposed portion remains due to insufficient radiation of light to a region to be exposed or an exposure defect that an area of actually exposed region becomes larger than an area of an intended exposed region hardly occurs.

However, in exposing the photosensitive material film using the direct exposure machine, the focal depth of the optical system is extremely shallow, that is, approximately ±4 μm, for example. Accordingly, when the substrate has surface irregularities, the exposure is influenced by the surface irregularities leading to an exposure defect that an unexposed portion remains due to insufficient radiation of light to a exposure unit region or, as an opposite case, an exposure defect that an area of actually exposed region becomes larger than an area of an intended exposed region, for example.

Accordingly, in exposing the photosensitive material film using the direct exposure machine, usually, it is desirable that the length measurement (distance measurement) is performed so as to decide a focal point of radiation light for every small region before exposure, and the exposure is performed while setting a focal point of light to be radiated to every small region to the decided focal point.

Here, the length measurement for every small region is performed such that, for example, light having a wavelength which does not expose a photosensitive material film is radiated, and a distance from an optical system to a photosensitive material film is calculated based on a position, intensity or the like of a reflection light.

In manufacturing liquid crystal display panels by a multiple-piece collective manufacturing, on a substrate on which scanning signal lines and the like are formed, for example, there exists a region where lines such as the scanning signal lines are not formed such as a separation region which separates two neighboring circuit forming regions from each other. Accordingly, when pixel electrodes which are connected to sources of the TFT elements are formed after forming the scanning signal lines, the video signal lines, the TFT elements and the like, for example, there may arise following drawbacks.

In forming the pixel electrodes, for example, the pixel electrodes are formed by etching a light-transmitting conductive film such as an ITO film. Here, when the exposure of a photosensitive material film formed on the conductive film is performed using the direct exposure machine, before the exposure is performed, for example, an optical system of the direct exposure machine performs a length measurement for every small region which the optical system can expose at a time so as to decide a focal point of a radiation light.

Here, in the circuit forming region, lines made of opaque metal such as the scanning signal lines and the video signal lines are formed, and sizes and arrangement intervals of these lines are set smaller than a size of the small region. Accordingly, in performing the length measurement of the small region within the circuit forming region, the radiation light is reflected on the scanning signal lines, the video signal lines or the like and hence, the distance from the optical system to the photosensitive material film can be calculated.

However, in the conventional multi-piece collective manufacturing, usually, lines and the like are not formed in the separation region which separates two neighboring circuit forming regions from each other as described above. Further, in the separation region, a plurality of insulation layers are interposed between the substrate and the light-transmitting conductive film. However, these insulation layers have light-transmitting property. Accordingly, in performing the length measurement of the small region where a region to which light for length measurement is applied is within the separation region, the intensity of a reflection light is weak so that an accurate distance from the optical system to the photosensitive material film cannot be calculated. Accordingly, a focal point of a radiation light may deviate or the focal point may not be determined with respect to such a small region thus leading to stopping of the device.

When the focal point of the light radiated to the small region deviates, for example, an unexposed portion remains on a photosensitive material film in an exposure unit region to be exposed or a photosensitive material film in an exposure unit region not to be exposed arranged adjacent to an exposure unit region to be exposed is also exposed. Accordingly, due to a defect in shape of a photosensitive material film (mask) obtained after development, for example, a defect in shape is generated in a light-transmitting conductive film obtained by etching using the photosensitive material film as a mask. As a result, for example, there arises a drawback that the deterioration of display quality of a liquid crystal display device, an operation failure of the liquid crystal display device or irregularities in display quality for every liquid crystal display device is liable to occur.

Further, when the device stops since a focal point cannot be decided, there arises a drawback that, for example, based on a result of the length measurement of another small region arranged in the vicinity of a small region where the focal point cannot be decided, it is necessary to decide the focal point of light to be radiated to the small region where the length measurement cannot be performed.

The above-mentioned drawbacks are not limited to the case where the photosensitive material film is exposed using the direct exposure machine. For example, even when a photosensitive material film is exposed using an exposure device which uses a photo mask, such drawbacks arise when a region to be exposed at a time is narrow and a focal depth is small.

It is an object of the present invention to provide a technique which, for example, in a manufacturing method of a liquid crystal display device, in dividing a photosensitive material film formed on a light-transmitting film into a plurality of small regions and sequentially exposing the respective small regions of the photosensitive material film, can decrease the deviation of a focal point among lights to be radiated to the respective small regions.

It is another object of the present invention to provide a technique which, for example, in a manufacturing method of a liquid crystal display device, can enhance exposure efficiency when a photosensitive material film formed on a light-transmitting film is divided into a plurality of small regions and the respective small regions are sequentially exposed.

It is still another object of the present invention to provide a technique which can suppress, for example, deterioration of display quality of a liquid crystal display device or irregularities in display quality for every liquid crystal display device.

The above-mentioned and other objects and novel technical features of the present invention will become apparent from the description of this specification and attached drawings.

To summarize typical inventions among inventions disclosed in this specification, they are as follows.

(1) According to one aspect of the present invention, there is provided a manufacturing method of a display device including the steps of: forming a light-transmitting film on a substrate; forming a photosensitive material film on the light-transmitting film; exposing the photosensitive material film using an exposure device; and developing the exposed photosensitive material film, wherein the step of exposing the photosensitive material film includes: a first step in which a whole exposure subject region of the photosensitive material film is divided into a plurality of small regions, and a focal point of light to be radiated to the small region is decided for every small region; and a second step in which the respective small regions are sequentially exposed while setting the focal points of light to be radiated to each small region to the focal point decided in the first step, wherein in the first step, the whole exposure subject region of the photosensitive material film is divided into a plurality of belt-like regions which extend in the same longitudinal direction, each belt-like region is divided into a plurality of length measurement unit regions arranged parallel to each other in the longitudinal direction, a distance from an optical system of the exposure device to the photosensitive material film is calculated for each length measurement unit region, and the focal point of light to be radiated to each small region is decided based on the calculated distance, and an opaque conductive layer is formed on said each length measurement unit region before the step of forming the light-transmitting film.

(2) In the manufacturing method of a display device having the constitution (1), the length measurement unit region has the same size as the small region.

(3) In the manufacturing method of a display device having the constitution (1), the small region is a quadrangular region which is surrounded by sides of the belt-like region extending in the longitudinal direction and sides of the belt-like region extending in the lateral direction, and in the length measurement unit region, a size of the belt-like region in the lateral direction is equal to a size of a small region in the lateral direction, and a size of the belt-like region in the longitudinal direction is two times or more larger than the size of the small region in the longitudinal direction.

(4) In the manufacturing method of a display device having the constitution (1), the small region is a quadrangular region which is surrounded by sides of the belt-like region extending in the longitudinal direction and sides extending in the lateral direction, and sets a size thereof in the lateral direction equal to a size of the belt-like region in the lateral direction, and the plurality of belt-like regions include the belt-like regions each of which is divided into the length measurement unit regions where the size of the belt-like region in the longitudinal direction is equal to the size of the small region, and the belt-like regions each of which is divided into the length measurement unit regions where the size of the belt-like region in the longitudinal direction is two times or more larger than the size of the small region.

(5) In the manufacturing method of a display device having the constitution (1), the first step and the second step are performed in parallel, and the respective small regions aligned in the longitudinal direction of the belt-like region are sequentially exposed in the second step.

(6) According to another aspect of the present invention, there is provided a manufacturing method of a display device in which a plurality of circuit forming regions are formed on one sheet of substrate, and a circuit including a plurality of scanning signal lines, a plurality of video signal lines, a plurality of TFT elements and a plurality of transparent electrodes is formed on each circuit forming region, wherein a separation region which separates two neighboring circuit forming regions from each other is provided between said two neighboring circuit forming regions, and in forming the scanning signal lines in said each circuit forming region, a conductive layer which is not electrically connected with the scanning signal lines is formed in the separation region simultaneously with the scanning signal lines.

(7) According to still another object of the present invention, there is provided a manufacturing method of a display device in which a plurality of circuit forming regions are formed on one sheet of substrate, and a circuit including a plurality of scanning signal lines, a plurality of video signal lines, a plurality of TFT elements and a plurality of transparent electrodes is formed on each circuit forming region, wherein a separation region which separates two neighboring circuit forming regions from each other is provided between said two neighboring circuit forming regions, and in forming the video signal lines in said each circuit forming region, a conductive layer which is not electrically connected with the video signal lines is formed in the separation region simultaneously with the video signal lines.

(8) In the manufacturing method of a display device having the constitution (6) or (7), the conductive layer has a grid-like planar shape.

(9) In the manufacturing method of a display device having the constitution (6) or (7), the conductive layer is made independently for every separation region.

(10) In the manufacturing method of a display device having the constitution (6) or (7), the plurality of circuit forming regions are arranged in a matrix array in the first direction and the second direction, and the conductive layer is formed only in the separation regions each of which separates said two circuit forming regions arranged adjacent to each other in the first direction out of the separation regions.

(11) In the manufacturing method of a display device having the constitution (6) or (7), the transparent electrode is an electrode which is connected to a source or a drain of the TFT element, and the scanning signal lines and the video signal lines are formed prior to the formation of the transparent electrodes.

(12) In the manufacturing method of a display device having the constitution (6) or (7), the transparent electrodes include first transparent electrodes each of which is connected to a source or a drain of the TFT element, and a second transparent electrode which is arranged between the substrate and the first transparent electrode, and the scanning signal lines and the video signal lines are formed prior to the formation of the first transparent electrodes.

(13) In the manufacturing method of a display device having the constitution (12), the scanning signal lines and the video signal lines are formed prior to the formation of the second transparent electrodes.

(14) According to a further object of the present invention, there is provided a display device having a display panel which arranges a plurality of lines, a plurality of TFT elements and a plurality of transparent electrodes on an insulation substrate, wherein an opaque conductive layer which is connected with none of the lines, the TFT elements and the transparent electrodes is arranged on an outer peripheral portion of the insulation substrate.

(15) In the display device having the constitution (14), the display panel is a liquid crystal display panel.

According to the manufacturing method of a display device of the present invention, in dividing the photosensitive material film formed on the light-transmitting film into the plurality of small regions and sequentially exposing the respective small regions of the photosensitive material film, it is possible to decrease the deviation of a focal point of light to be radiated to the respective small regions.

Further, according to the manufacturing method of a display device of the present invention, it is possible to enhance exposure efficiency when the photosensitive material film formed on the light-transmitting film is divided into the plurality of small regions and the respective small regions of the photosensitive material film are sequentially exposed.

Further, a display device which is manufactured using the manufacturing method of a display device of the present invention can, for example, decrease a defect in shape of a conductive layer obtained by etching the light-transmitting conductive film. Accordingly, for example, it is possible to suppress the deterioration of display quality of a liquid crystal display device or irregularities in display quality for every liquid crystal display device.

### BRIEF DESCRIPTION OF THE DRAWINGS

FIG. 1A is a schematic plan view showing one example of the schematic constitution of a liquid crystal display panel;

FIG. 1B is a schematic circuit diagram showing one example of the circuit constitution of one pixel of the liquid crystal display panel;

FIG. 2A is a schematic view showing one example of the manufacturing method of a liquid crystal display panel by multiple-piece collective manufacturing;

FIG. 2B is a schematic view showing one example of a method of exposing a photosensitive material film;

FIG. 3A is a schematic plan view showing one example of the relationship between a circuit forming region of a mother glass and a small region at the time of exposing a photosensitive material film;

FIG. 3B is a schematic cross-sectional view showing one example of length measurement of a small region EA1 in FIG. 3A;

FIG. 3C is a schematic cross-sectional view showing one example of length measurement of a small region EA2 in FIG. 3A;

FIG. 4 is a schematic view for explaining the summary of a manufacturing method of a liquid crystal display panel according to an embodiment 1 of the present invention;

FIG. 5 is a schematic view for explaining the summary of a manufacturing method of a liquid crystal display panel according to an embodiment 2 of the present invention;

FIG. 6A is a schematic view showing one example of an arrangement method of a light reflection layer for one belt-like region in a manufacturing method of a liquid crystal display panel according to an embodiment 3 of the present invention;

FIG. 6B is a schematic view showing another example of the arrangement method of the light reflection layer for one belt-like region;

FIG. 6C is a schematic view showing one example of the arrangement method of the light reflection layer for a mother glass;

FIG. 7A is a schematic view showing a first modification of the manufacturing method of a liquid crystal display panel according to the embodiment 3;

FIG. 7B is a schematic view showing a second modification of the manufacturing method of a liquid crystal display panel according to the embodiment 3;

FIG. 7C is a schematic view showing a third modification of the manufacturing method of a liquid crystal display panel according to the embodiment 3; and

FIG. 8 is a schematic view for explaining an application example of the manufacturing method of a display device of the present invention.

### DESCRIPTION OF THE PREFERRED EMBODIMENT

Hereinafter, the present invention is explained in detail in conjunction with embodiments by reference to drawings.

Here, in all drawings for describing the embodiments, parts having identical functions are given the same symbols and their repeated explanation is omitted.

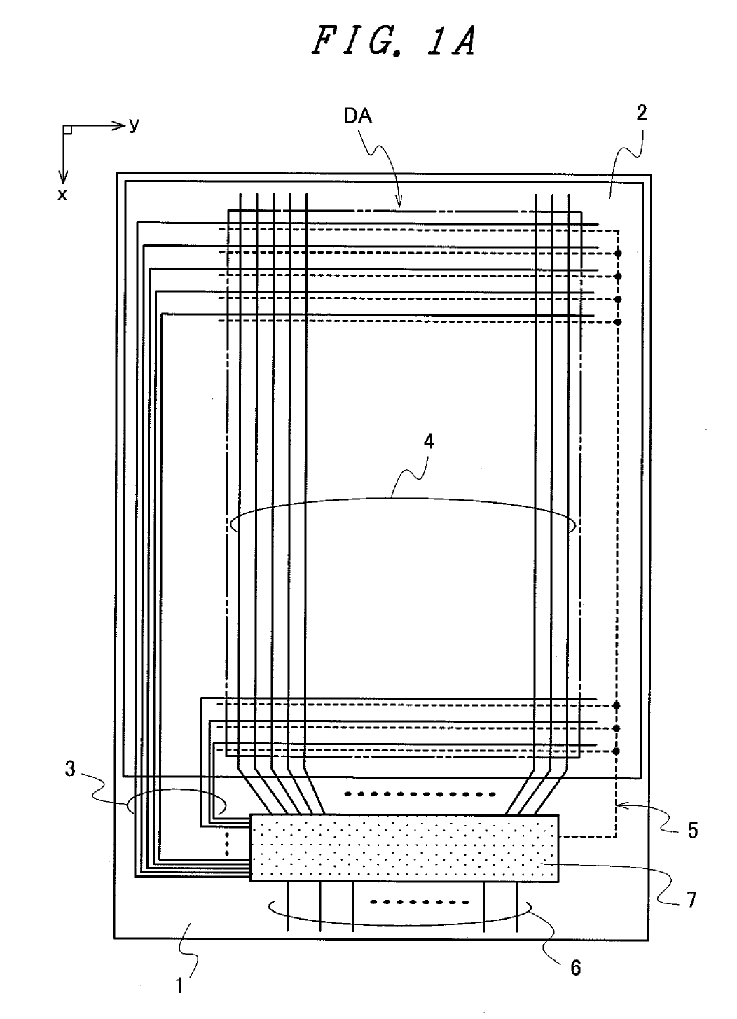

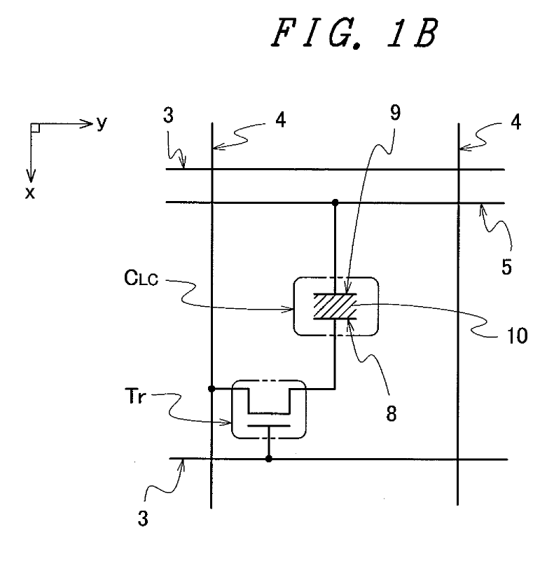

FIG. 1A and FIG. 1B are schematic views showing one example of the schematic constitution of a display device which is desirable to be manufactured by the manufacturing method of a display device of the present invention.

FIG. 1A is a schematic plan view showing one example of the schematic constitution of a liquid crystal display panel. FIG. 1B is a schematic circuit diagram showing one example of the circuit constitution of one pixel of the liquid crystal display panel.

The present invention relates to a step of exposing a photosensitive material film formed on a light-transmitting film in a manufacturing method of a display device. The manufacturing method of a display device having such a step is, for example, a manufacturing method of a liquid crystal display panel in a manufacturing method of a liquid crystal display device.

The liquid crystal display panel includes, for example, as shown in FIG. 1A, a first substrate 1 and a second substrate 2, and a liquid crystal material not shown in the drawing is sealed between these substrates 1, 2. Here, on the first substrate 1, for example, a plurality of scanning signal lines 3, a plurality of video signal lines 4, common lines 5, signal input lines 6 and the like are arranged. Further, on the first substrate 1, for example, a drive circuit 7 which drives the liquid crystal display panel is mounted.

A display region DA of the liquid crystal display panel is divided into a plurality of pixels. One pixel includes, for example, as shown in FIG. 1B, a TFT element Tr and a liquid crystal capacitance C_{LC} (also referred to as pixel capacitance) which is formed by a pixel electrode 8, a common electrode 9, and a liquid crystal layer 10.

The TFT element Tr has a gate thereof connected to one scanning signal line 3, and a drain thereof connected to one video signal line 4. Further, the TFT element Tr has a source thereof connected to the pixel electrode 8. Here, the source and the drain of the TFT element Tr are changed corresponding to the bias direction, that is, the relationship between a potential of the video signal line 4 and a potential of the pixel electrode 8 during a period in which the gate of the TFT element Tr is in an ON state.

Further, the common electrode 9 is connected to the common line 5 so that a voltage of a predetermined potential (common potential) is applied to the common electrode 9. When the liquid crystal display panel is a lateral-electric-field-drive liquid crystal display panel such as an IPS-method liquid crystal display panel, the common electrodes 9 are formed on the first substrate 1. When the liquid crystal display panel is a vertical-electric-field-drive liquid crystal display panel such as a VA-method liquid crystal display panel or a TN-method liquid crystal display panel, the common electrodes 9 are formed on the second substrate 2.

Further, the liquid crystal layer 10 is made of a liquid crystal material which is sealed between the first substrate 1 and the second substrate 2.

Further, one pixel formed in the liquid crystal display panel is not limited to the constitution shown in FIG. 1B, and may be constituted of, for example, the pixel electrode 8, a conductive layer different from the video signal line 4 and the common electrode 9, and a holding capacitance which is formed of an insulation layer.

In a conventional manufacturing method of a liquid crystal display panel, irrespective of the constitution of the pixel, the pixel electrodes 8 are formed by etching a transparent conductive film in general. That is, the conventional manufacturing method of a liquid crystal display panel includes, irrespective of the constitution of the pixel, a step of exposing a photosensitive material film formed on a light-transmitting conductive film in general. The present invention exhibits advantageous effects when the present invention is applied to a step of exposing a photosensitive material film formed on a transparent conductive film such as an ITO film in forming the pixel electrodes 8. Accordingly, in this specification, the explanation of the specific constitution of a circuit formed on the first substrate 1 is omitted.

It is needless to say that while the present invention acquires the advantageous effect in forming the transparent conductive film, the present invention can also acquire the same advantageous effect in forming an inorganic insulation film made of SiN or SiO or in forming a photosensitive organic insulation film.

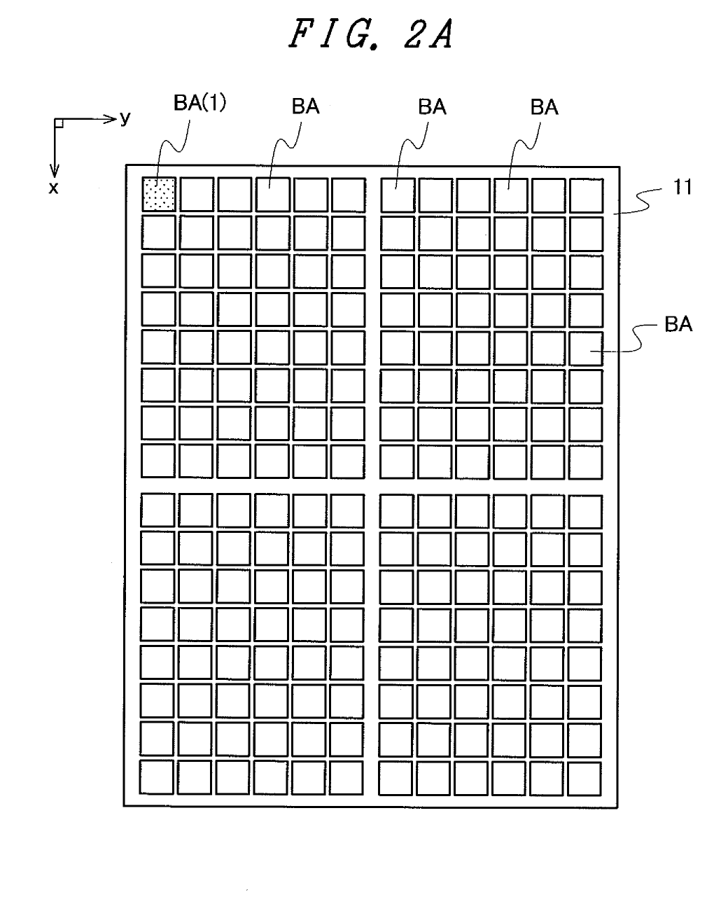

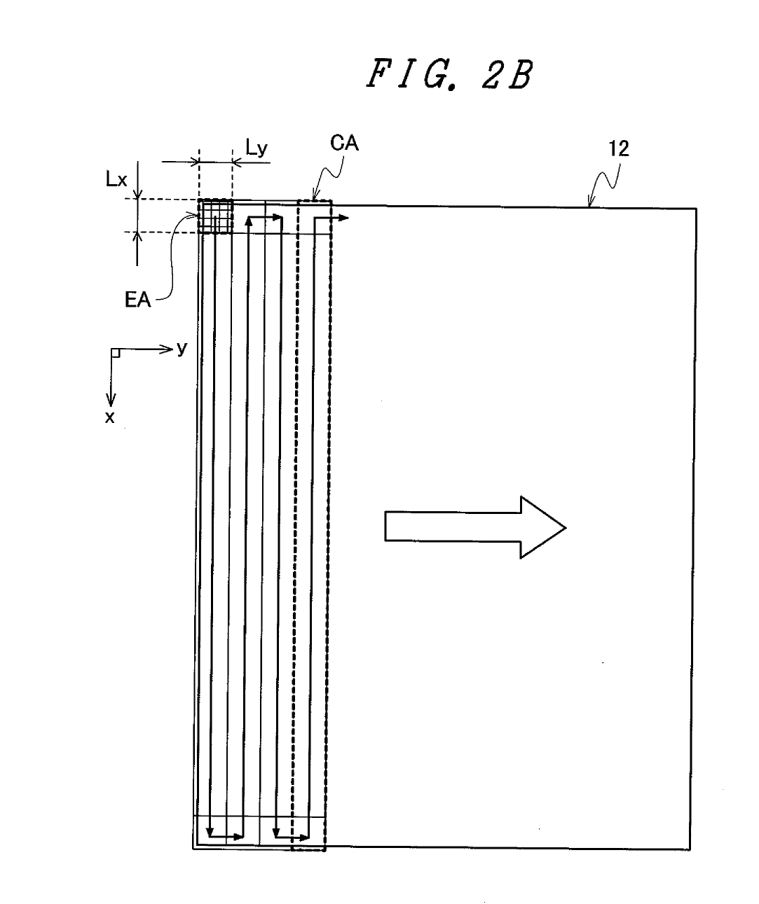

FIG. 2A and FIG. 2B are schematic views for explaining one example of a manufacturing method of a liquid crystal display panel.

FIG. 2A is a schematic view showing one example of the manufacturing method of a liquid crystal display panel by multiple-piece collective manufacturing. FIG. 2B is a schematic view showing one example of a method of exposing a photosensitive material film.

The liquid crystal display panel having the constitution shown in FIG. 1A is used as a liquid crystal display of a portable electronic apparatus such as a mobile phone terminal, for example. A diagonal size of the display region DA is approximately several inches. In manufacturing such a liquid crystal display panel, usually, the liquid crystal display panel is manufactured by a method which is referred to as multiple-piece collective manufacturing. Here, multiple-piece collective manufacturing is a general term for a method in which a plurality of liquid crystal display panels are collectively manufactured using a pair of substrates (mother glasses). A method in which N pieces (integer of 2 or more) of liquid crystal display panels are collectively manufactured may also be referred to as N-piece collective manufacturing.

In manufacturing a liquid crystal display panel in which a diagonal size of the display region DA is approximately 3 inches by multiple-piece collective measuring, for example, the pair of mother glasses each of which has a size of 730 mm×920 mm is used. Here, on a mother glass 11 which becomes the first substrates 1 of the respective liquid crystal display panels, for example, as shown in FIG. 2A, 192 pieces of regions BA (hereinafter referred to as circuit forming regions) each of which becomes the first substrate 1 are set. In each one of 192 pieces of circuit forming regions BA, a circuit constituted of the scanning signal lines 3, the video signal lines 4, the TFT element Tr, the pixel electrode 8 and the like is formed.

In forming the pixel electrode 8 in the respective circuit forming regions BA of the mother glass 11, usually, the pixel electrodes 8 are formed by etching a transparent conductive film formed on the whole surface of the mother glass 11. Further, in etching the transparent conductive film, a mask (etching resist) is formed by forming a photosensitive material film on the transparent conductive film and by exposing and developing the photosensitive material film.

The exposure of the photosensitive material film is conventionally performed using an exposure device which uses a photo mask in general. However, the partial correction of the photo mask is substantially impossible. Accordingly, when a defect in shape occurs in a pattern obtained by exposing and developing the photosensitive material film, a conductive film formed by etching using the pattern as a mask or the like, there arises a drawback that it is necessary to form a new photo mask, for example.

Accordingly, recently, as a manufacturing method of a liquid crystal display panel which can overcome such a drawback, there has been proposed a manufacturing method of a liquid crystal display panel in which a photosensitive material film is exposed using an exposure device which is referred to as a direct exposure machine, for example.

The direct exposure machine is an exposure device which includes MEMS (Micro Electro Mechanical Systems) which are referred to as a DMD (Digital Mirror Device) or a GLV (Grating Light Valve), for example, and controls a pattern of a light to be radiated to an exposure subject region by a numerical control based on layout data prepared by a CAD or the like.

However, in exposing the photosensitive material film using the direct exposure machine, the radiation/non-radiation of light is controlled for every minute region (drawing resolution unit region) of 0.5 μm×0.5 μm or 0.25 μm×0.25 μm, for example. Accordingly, in exposing the photosensitive material film using the direct exposure machine, for example, as shown in FIG. 2B, an exposure subject region 12 is divided into small regions EA each of which has a lateral size (y-direction size) Ly and a longitudinal size (x-direction size) Lx, and the respective small regions EA are sequentially exposed. (In an actual exposure operation, the exposure is performed by continuously radiating light by scanning the substrate in the longitudinal direction for every lateral size Ly). The lateral size Ly and the longitudinal size Lx of the small region EA are approximately 4 mm respectively, for example.

Here, the exposure of the photosensitive material film is performed such that, for example, the exposure subject region 12 is divided into a plurality of belt-like regions CA which set the x direction as the longitudinal direction, and the respective belt-like regions CA are sequentially exposed. Each belt-like region CA is constituted of a plurality of small regions EA having a lateral size (y-direction size) Ly which are arranged in the longitudinal direction, for example.

Here, the exposure of the plurality of small regions EA Included in one belt-like region CA starts from the exposure of the small region EA which is positioned at one end out of the plurality of small regions EA, for example, and the exposure of the photosensitive material film is performed up to the small region EA which is positioned on the other end by displacing the x-direction positional relationship between an optical system of the direct exposure machine and the mother glass 11 (exposure subject region 12).

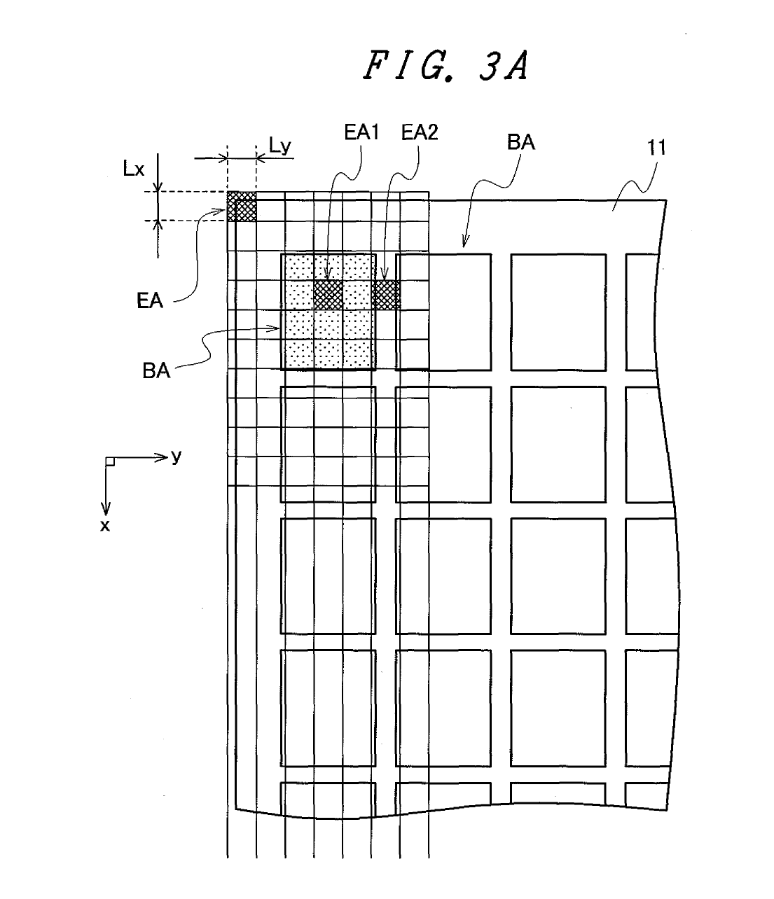

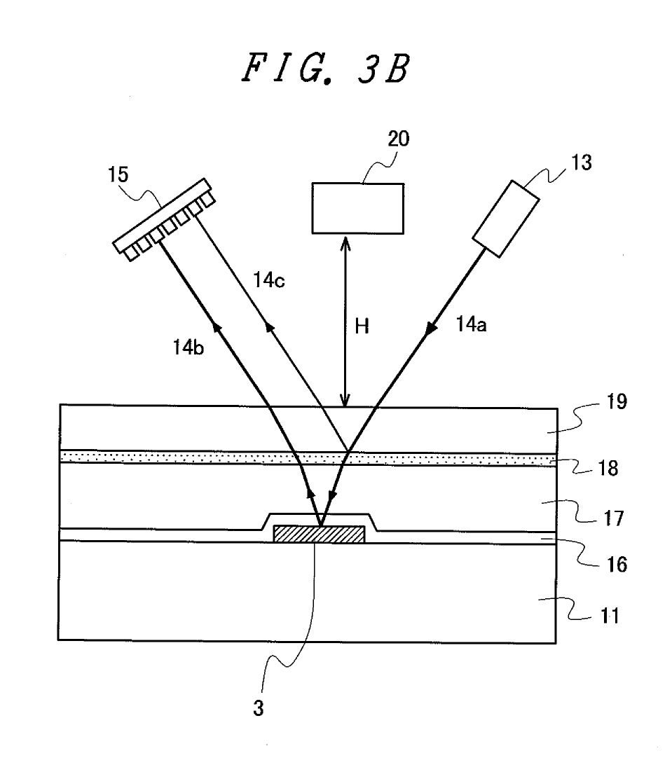

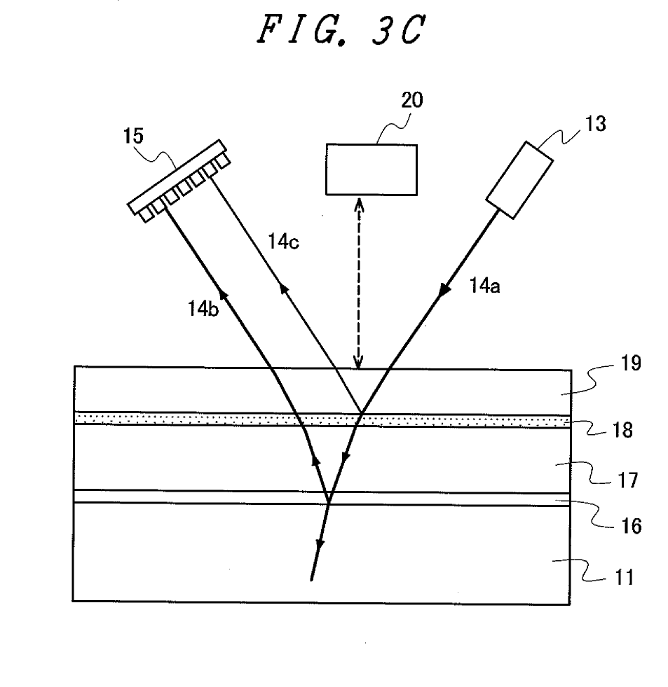

FIG. 3A to FIG. 3C are schematic views for explaining one example of drawbacks which a conventional method of exposing a photosensitive material film using a direct exposure machine has.

FIG. 3A is a schematic plan view showing one example of the relationship between a circuit forming region of a mother glass and a small region at the time of exposing a photosensitive material film. FIG. 3B is a schematic cross-sectional view showing one example of the length measurement of the small region EA1 in FIG. 3A. FIG. 3C is a schematic cross-sectional view showing one example of the length measurement of the small region EA2 in FIG. 3A.

The mother glass 11 used in manufacturing the liquid crystal display panels by multiple-piece collective manufacturing has a large area, and has surface irregularities on a surface thereof on which the scanning signal lines 3 and the like are formed, for example. Here, the photosensitive material film formed on the mother glass 11 is influenced by the surface irregularities of the mother glass 11 and hence, a film thickness of the photosensitive material film becomes non-uniform or a surface of the photosensitive material film becomes uneven.

Further, in exposing a photosensitive material film by a direct exposure machine, the radiation/non-radiation of light is, as mentioned previously, controlled for every minute region of 0.5 μm×0.5 μm or 0.25 μm×0.25 μm, for example. In the direct exposure machine which realizes high-resolution drawing and performs the exposure with the small exposure region EA of approximately 4 mm square at a time so that a lens diameter of an optical system is small, a focal depth becomes shallow, for example, approximately ±4 μm.

Accordingly, in exposing the photosensitive material film using the direct exposure machine compatible with high resolution, to prevent an exposure defect, for example, it is preferable to perform the exposure in a state where a focal point of radiation light is set for every small region EA.

Here, the focal point of light to be radiated to each small region EA is decided by performing the length measurement for every small region EA, that is, the measurement of a distance from an optical system which radiates light for exposing the photosensitive material film to the photosensitive material film. The distance from the optical system to the photosensitive material film is calculated, for example, based on a result obtained by measuring a position and intensity of a reflection light when light having a wavelength which does not expose the photosensitive material film is radiated to the photosensitive material film. In the explanation made hereinafter, the light for exposing the photosensitive material film is referred to as “exposure light”, and the light for measuring the distance from the optical system to the photosensitive material film is referred to as “length measurement light”.

In manufacturing liquid crystal display panels by multiple-piece collective measuring, the circuit forming region BA of the mother glass 11 and the small region EA when the photosensitive material film is exposed using the direct exposure machine have the relationship shown in FIG. 3A, for example.

The formation of the pixel electrodes 8 on the mother glass 11 includes a step of forming a transparent conductive film such as an ITO film, a step of forming a photosensitive material film on the transparent conductive film, a step of deciding a focal point of exposure light for every small region EA, a step of exposing the photosensitive material film for every small region EA, and a step of developing the photosensitive material film.

Further, the step of forming the pixel electrodes 8 on the mother glass 11 is usually performed after a step of forming the scanning signal lines 3 and a step of forming the video signal lines 4.

Accordingly, for example, as in the case of the small region EA1 shown in FIG. 3A, in the small region whose entirety is within the circuit forming region BA, the scanning signal lines 3, the video signal lines 4 and the like are present between the transparent conductive film used for forming the pixel electrode 8 and the mother glass 11. Here, the scanning signal lines 3 and the video signal lines 4 are made of metal such as aluminum, for example, and hence, these lines exhibit high light reflectance. Further, on the mother glass 11, a plurality of transparent insulation layers are formed besides the scanning signal lines 3, the video signal lines 4 and the like.

Accordingly, when the length measurement light is radiated to the small region EA1, for example, as shown in FIG. 3B, a length measurement light 14a radiated from a light source 13 is reflected on the scanning signal line 3, a reflection light 14b is detected by a photo sensor 15.

Here, on the mother glass 11, a first insulation layer 16, a second insulation layer 17 and the like are formed besides the scanning signal lines 3, the video signal lines and the like, for example. On the second insulation layer 17, a transparent conductive film 18 and a photosensitive material film 19 are formed. Accordingly, some of the length measurement light 14a radiated from the light source 13 is reflected on an interface between the photosensitive material film 19 and the transparent conductive film 18 or the like, for example, and a reflection light 14c may be detected by the photo sensor 15. However, intensity of the reflection light 14c is extremely low compared to the intensity of the reflection light 14b. Accordingly, with respect to the small region EA1, it is possible to calculate a distance H from the optical system 20 for radiating exposure light to the photosensitive material film 19 based on intensity, a detection position and the like of the reflection light 14b and hence, it is also possible to decide a focal point of the exposure light.

On the other hand, for example, as in the case of the small region EA2 shown in FIG. 3A, in the small region whose entirety substantially falls within a separation region which separates two neighboring circuit forming regions BA from each other, lines such as the scanning signal lines 3, the video signal lines 4 and the like are not usually present between the transparent conductive film for forming the pixel electrode 8 and the mother glass 11.

Accordingly, when the length measurement light is radiated to the small region EA2, for example, as shown in FIG. 3C, the length measurement light 14a radiated from the light source 13 continues refraction, and is radiated from a back surface of the mother glass 11.

Also in the small region EA2, on the mother glass 11, the first insulation layer 16, the second insulation layer 17 and the like are formed, for example. On the second insulation layer 17, the transparent conductive film 18 and the photosensitive material film 19 are formed. Accordingly, some of length measurement light 14a radiated from the light source 13 is reflected on an interface between the photosensitive material film 19 and the transparent conductive film 18, an interface between the first insulation layer 16 and the mother glass 11 and the like, and the reflection light 14c and a reflection light 14d may be detected by the optical sensor 15. However, intensities of the reflection light 14c, 14d are extremely small compared to the intensity of the reflection light 14b reflected on the metal film such as the scanning signal line 3. Accordingly, with respect to the small region EA2, it is difficult to accurately calculate the distance between an optical system 20 and the photosensitive material film 19, and it is impossible to decide an accurate focal point of exposure light.

Accordingly, in a conventional method of exposing a photosensitive material film, at the time of radiating exposure light to the small region, for example, there may be a case where an abnormal state (error) where a focusing cannot be performed occurs so that an exposure device stops. Because of stopping of the exposure device, the conventional manufacturing method of a liquid crystal display panel has a drawback that manufacturing efficiency is lowered.

Further, in the conventional method of exposing a photosensitive material film, at the time of radiating exposure light to the small region, for example, there may be a case where the exposure is performed in a state where focusing is not acquired leading to an exposure defect. Accordingly, a liquid crystal display device having a liquid crystal display panel which is manufactured by the conventional manufacturing method has a drawback that the deterioration of display quality or an operation failure attributed to an exposure defect or irregularities in display quality among liquid crystal display devices is liable to occur, for example.

### Embodiment 1

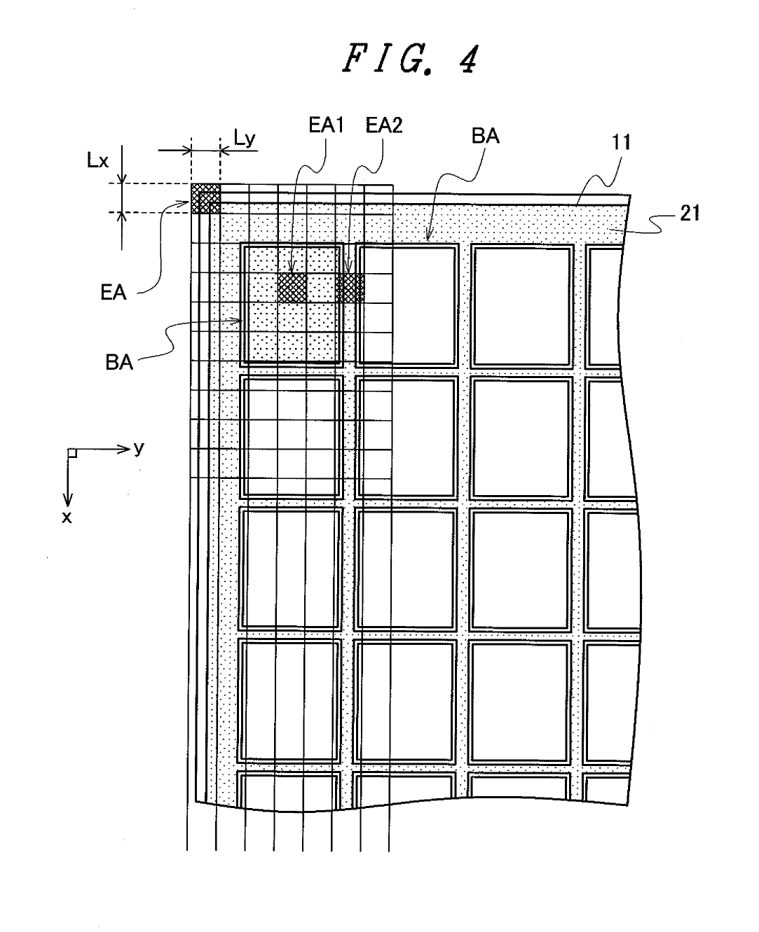

FIG. 4 is a schematic view for explaining the summary of a manufacturing method of a liquid crystal display panel according to an embodiment 1 of the present invention.

In the embodiment 1, as an example of the manufacturing method of a display device to which the present invention is applied, a manufacturing method of a liquid crystal display panel is named.

In manufacturing the liquid crystal display panel, for example, firstly, the scanning signal lines 3, the video signal lines 4, the TFT elements Tr, the pixel electrodes 8 and the like are formed on a plurality of respective circuit forming regions BA of the mother glass 11. Here, the pixel electrodes 8 are usually formed after forming the scanning signal lines 3, the video signal lines 4 and the TFT elements Tr. The pixel electrodes 8 are formed by etching a transparent conductive film such as an ITO film. Accordingly, a step of forming the pixel electrodes 8 includes a step of forming the transparent conductive film, a step of forming a photosensitive material film on the transparent conductive film, a step of exposing and developing the photosensitive material film, and a step of etching the transparent conductive film.

Here, in exposing the photosensitive material film by a direct exposure machine, prior to the exposure, as described previously, the exposure subject region 12 is divided into a plurality of small regions EA (each region being a region which can be exposed at a time), and a focal point of exposure light is decided for every small region EA.

For this end, in the manufacturing method of a liquid crystal display panel according to the embodiment 1, prior to the formation of the pixel electrodes 8, that is, prior to the formation of the transparent conductive film 18 and the photosensitive material film 19, as shown in FIG. 4, a grid-like light reflection layer 21 made of a material which exhibits high light reflectance is formed outside the respective circuit forming regions BA on a surface of the mother glass 11, for example.

Here, in the small region EA1, between the photosensitive material film 19 and the mother glass 11, opaque metal lines such as the scanning signal lines 3 which function as light reflection layers are present. Accordingly, the distance between the optical system 20 and the photosensitive material film 19 in the small region EA1 can be calculated based on intensity and a detection position of the reflection light 14b reflected on the scanning signal line 3 as shown in FIG. 3A, for example.

Further, in the small region EA2, the light reflection layer 21 is present between the photosensitive material film 19 and the mother glass 11. Accordingly, the distance between the optical system 20 and the photosensitive material film 19 in the small region EA2 can be calculated based on intensity and a detection position of reflection light reflected on the light reflection layer 21.

That is, in the manufacturing method of a liquid crystal display panel according to the embodiment 1, the light reflection layer 21 is formed prior to the formation of the transparent conductive film 18, and the distance between the optical system 20 and the photosensitive material film 19 in the small region where the scanning signal lines 3, the video signal lines 4 and the like are not present can be calculated.

Accordingly, in the manufacturing method of a liquid crystal display panel according to the embodiment 1, in exposing the photosensitive material film 19, it is possible to prevent the occurrence of a state where the exposure device stops because a focal point of exposure light cannot be decided, for example. Further, the light reflection layer 21 is formed outside the circuit forming regions BA and hence, for example, the light reflection layer 21 can be formed in the step of forming the scanning signal lines 3. Accordingly, the manufacturing method of a liquid crystal display panel according to the embodiment 1 can prevent the deterioration of manufacturing efficiency, for example.

Further, the manufacturing method of a liquid crystal display panel according to the embodiment 1 can prevent the occurrence of a state where the exposure is performed in a state focusing is not acquired so that an exposure defect occurs, for example. Accordingly, a liquid crystal display device having a liquid crystal display panel manufactured by the manufacturing method according to the embodiment 1 can also prevent the deterioration of display quality and an operation failure attributed to an exposure defect or irregularities in display quality for every liquid crystal display device, for example.

The method of forming the light reflection layer 21 explained in conjunction with the embodiment 1 is not limited to the case where the exposure of the photosensitive material film is performed using the direct exposure machine in the step of forming the pixel electrodes 8. For example, the method of forming the light reflection layer 21 explained in conjunction with the embodiment 1 is also effectively applicable to a case where the exposure of the photosensitive material film formed on a surface of the transparent insulation layer is performed using the direct exposure machine, and exposure light is radiated to the small region EA where the lines such as the scanning signal lines 3 are not formed.

Here, the light reflection layer 21 may be formed prior to the formation of the light-transmitting film such as the transparent conductive film 18 and the photosensitive material film 19. Accordingly, the step in which the light reflection layer 21 is formed is not always performed in the step of forming the scanning signal lines 3, and the light reflection layer 21 may be formed in the step of forming the video signal lines 4, for example. Further, the light reflection layer 21 may be formed in an independent step different from the step of forming the scanning signal lines 3 or the step of forming the video signal lines 4, for example. In this case, a material for forming the light reflection layer 21 is not limited to an opaque metal film, and the light reflection layer 21 may be formed using a resin such as a white resin which exhibits high light reflectance, for example.

In the manufacturing method of a liquid crystal display panel according to the embodiment 1, in exposing the photosensitive material film 19 formed on the light-transmitting film such as the transparent conductive film 18, the exposure subject region is divided into the plurality of small regions, and the respective small regions are sequentially exposed. Further, prior to the exposure of the photosensitive material film 19, the focal point of exposure light is decided for every small region EA.

Here, the step of deciding the focal point of the exposure light and the step of exposing the photosensitive material film 19 may be performed individually. However, to take the sequential exposure of the respective small regions EA of the photosensitive material film 19 in exposing the photosensitive material film 19 into consideration, it is desirable to perform the above-mentioned two steps in parallel.

When the step of deciding the focal point of exposure light and the step of exposing the photosensitive material film 19 are performed in parallel, for example, the first light source 13, the photo sensor 15 and a means for deciding the focal point (program or the like) may be incorporated into the direct exposure machine.

In exposing the photosensitive material film 19 using the direct exposure machine having the above-mentioned constitution, for example, during a period in which exposure light is radiated to a certain small region, a focal point of the exposure light may be decided by performing the length measurement with respect to the small region to which exposure light is radiated subsequently. Here, the small region to which the length measurement is applied may be any small region which is not yet exposed. Accordingly, the positional relationship between the small region to which exposure light is radiated and the small region to which the length measurement is applied is suitably changeable.

Further, the manufacturing method of a liquid crystal display panel according to the embodiment 1 is applicable to any method of exposing a photosensitive material film provided that an exposure subject region is divided into a plurality of small regions, the respective small regions of the photosensitive material film are sequentially exposed, and a focal point of the exposure light is decided for every small region before the exposure. Accordingly, an exposure device which exposes the photosensitive material film 19 is not limited to a direct exposure machine. For example, the exposure of the photosensitive material film 19 may be performed using an exposure device which sequentially exposes the respective small regions EA of the photosensitive material film 19 using photo masks having a small area.

### Embodiment 2

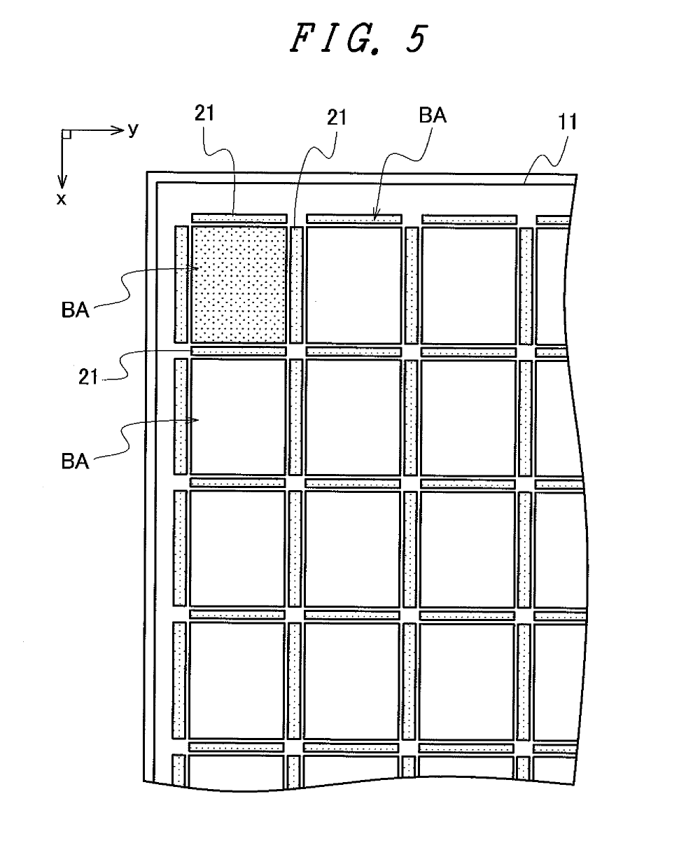

FIG. 5 is a schematic view for explaining the summary of a manufacturing method of a liquid crystal display panel according to an embodiment 2 of the present invention.

In the embodiment 1, for example, the grid-like light reflection layer 21 shown in FIG. 4 is formed and, in all small regions EA, the accurate distance from the optical system 20 to the photosensitive material film 19 can be measured (calculated) based on intensity and the detection position of the reflection light 14b reflected on either one of the metal line such as the scanning signal line 3 or the light reflection layer 21.

However, the distance from the optical system 20 to the photosensitive material film 19 in a certain small region EA can be estimated based on the distance from the optical system 20 to the photosensitive material film 19 which is already measured (calculated) with respect to another small region arranged around the small region EA, for example.

Accordingly, the light reflection layer 21 may be formed in a pattern where a plurality of light reflection portions each having a strip shape extend along sides of each circuit forming region BA as shown in FIG. 5, for example.

Further, in the manufacturing method of a liquid crystal display panel according to the embodiment 2, the length measurement performed for deciding the focal point of exposure light is performed only with respect to the small regions EA where the metal lines such as the scanning signal lines 3 or the light reflection layer 21 are present, for example. Then, with respect to the small regions EA where neither the metal lines nor the light reflection layer 21 are present, in place of the length measurement, interpolation processing which uses a result of length measurement of the surrounding small regions is performed thus estimating the distance from the optical system 20 to the photosensitive material film 19 whereby the focal point of exposure light is determined.

Here, the discrimination of the small regions where the metal lines or the light reflection layer 21 are present and the small regions where neither the metal lines nor the light reflection layer 21 are present may be performed using layout data stored in a data base of the direct exposure machine, for example.

### Embodiment 3

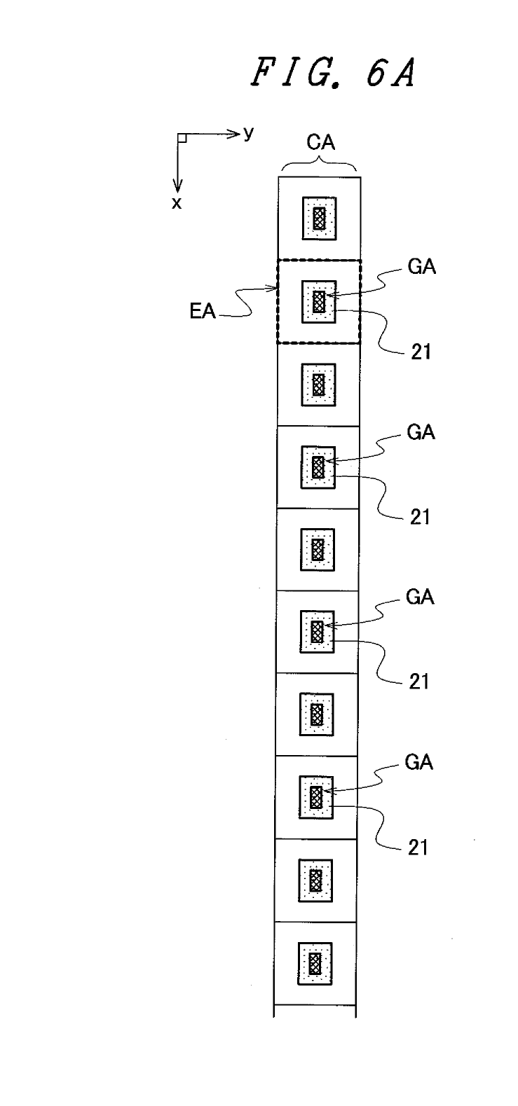

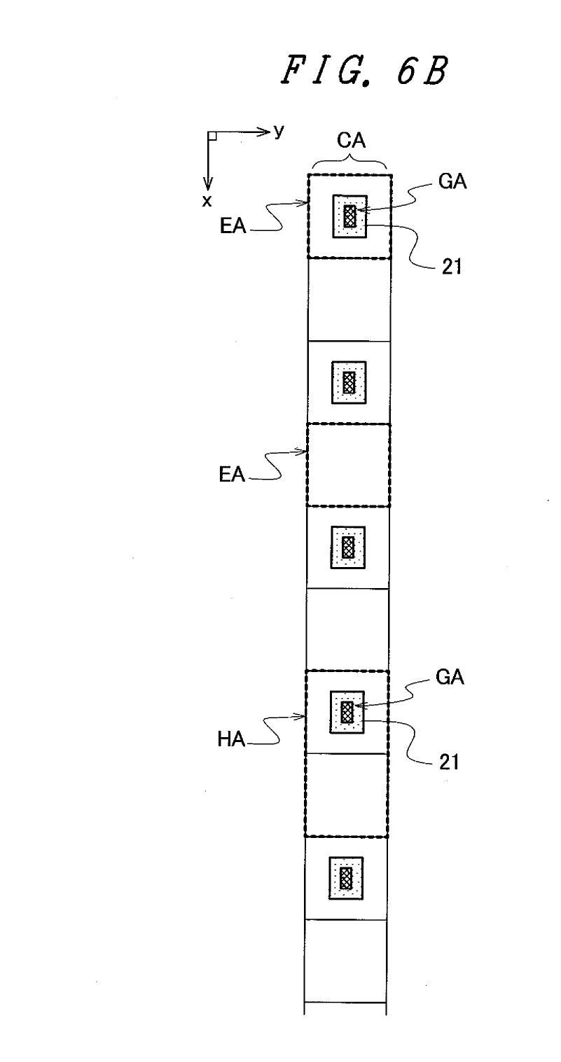

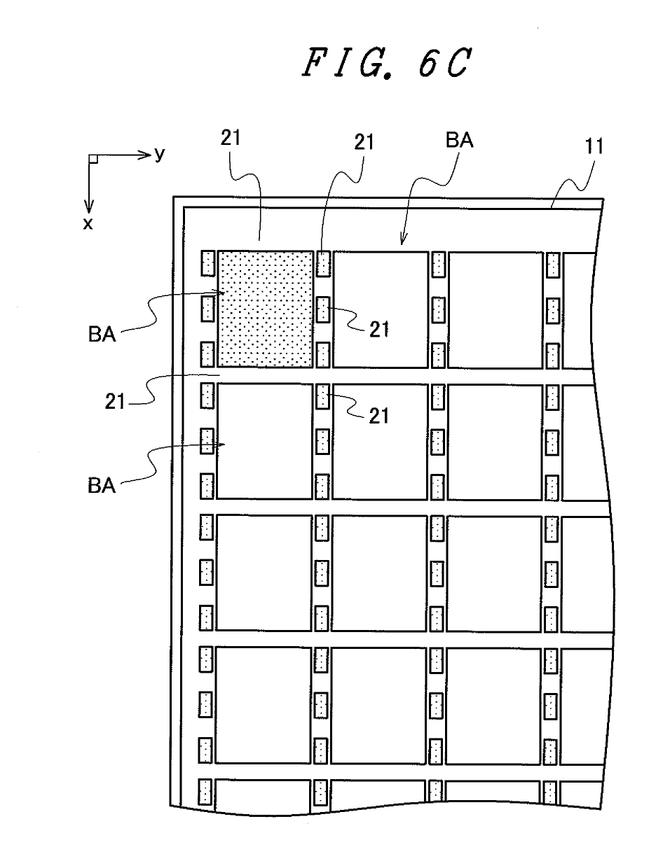

FIG. 6A to FIG. 6C are schematic views for explaining the summary of a manufacturing method of a liquid crystal display panel according to an embodiment 3 of the present invention.

FIG. 6A is a schematic view showing one example of an arrangement method of a light reflection layer for one belt-like region in a manufacturing method of a liquid crystal display panel according to an embodiment 3 of the present invention. FIG. 6B is a schematic view showing another example of the arrangement method of the light reflection layer for one belt-like region. FIG. 6C is a schematic view showing one example of the arrangement method of the light reflection layer for a mother glass.

In the embodiment 1, for example, the grid-like light reflection layer 21 shown in FIG. 4 is formed and, in all small regions EA, the accurate distance from the optical system 20 to the photosensitive material film 19 can be calculated based on intensity and the detection position of the reflection light 14b reflected on either one of the metal line such as the scanning signal line 3 or the light reflection layer 21.

The distance from the optical system 20 to the photosensitive material film 19 is usually calculated based on a position and intensity of the reflection light of the length measurement light 14a radiated to the small region EA as described previously. Here, the length measurement light 14a is not usually radiated to the whole small area EA, but is radiated only to a partial region (representative region GA) of the small region EA as shown in FIG. 6A, for example. The representative region GA has an area of, for example, approximately 30 μm×300 μm. Then, by regarding the distance from the optical system 20 to the photosensitive material film 19 in the whole small region EA as being equal to the distance from the optical system 20 to the photosensitive material film 19 in the representative region GA, a focal point of the exposure light to be radiated to the small region EA can be decided.

Accordingly, in providing the light reflection layer 21 between the photosensitive material film 19 and the mother glass 11 as in the case of the small region EA2 in the separation region which separates two neighboring circuit forming regions BA from each other, for example, as shown in FIG. 6A, the light reflection layers 21 may be provided in a scattered manner like dots such that each light reflection layer 21 is arranged only in the representative region GA and on the periphery of the representative region GA.

In the example shown in FIG. 6A, each small region EA has the representative region GA. That is, in the example shown in FIG. 6A, a unit region for measuring the distance from the optical system 20 to the photosensitive material film 19 (length measurement unit region) has the same size as the small region EA. However, a focal point of the exposure light to be radiated to the small region EA may also be decided by performing interpolation processing using the distance from the optical system 20 to the photosensitive material film 19 measured (calculated) with respect to another small region around the small region as explained in conjunction with the embodiment 2, for example.

Accordingly, when the light reflection layer 21 is provided in a scattered manner like dots, for example, as shown in 6B, by regarding two small regions EA arranged adjacent to each other in the longitudinal direction (x direction) of the belt-like region CA as being one length measurement unit region HA, the representative region GA and the light reflection layer 21 may be provided at a rate of one representative region GA and one light reflection layer 21 for every two neighboring small regions EA.

Here, a focal point of exposure light to be radiated to the small region EA where neither the representative region GA nor the light reflection layer 21 is present may be decided only based on the distance from the optical system 20 to the photosensitive material film 19 in the representative region GA of the length measurement unit region HA to which the small region EA belongs, for example, or may be decided based on the distance from the optical system 20 to the photosensitive material film 19 in a plurality of representative regions GA around the small region EA.

Further, in the example shown in FIG. 6B, two small regions EA arranged adjacent to each other in the x direction are set as one length measurement unit region. However, the embodiment is not limited to such an example, and three or more small regions EA arranged continuously in the x direction may be set as one length measurement unit region HA.

Further, insetting two or more small regions EA arranged adjacent to each other in the x direction as one length measurement unit region HA, it is needless to say that the position of the representative region GA and the position of the light reflection layer 21 are not limited to positions shown in FIG. 6B, and the representative region GA and the light reflection layer 21 may be provided in the vicinity of the center of one length measurement unit region HA, for example.

In view of the above-mentioned constitution, in the manufacturing method of a liquid crystal display panel according to the embodiment 3, prior to the formation of the transparent conductive film 18 and the photosensitive material film 19 on the mother glass 11, for example, as shown in FIG. 6C, the light reflection layers 21 each having a small area are provided to the separation region which separates two neighboring circuit forming regions BA from each other in a scattered manner like dots.

Accordingly, in the manufacturing method of a liquid crystal display panel according to the embodiment 3, for example, when the decision of a focal point of exposure light to be radiated to the small region EA and the exposure for every small region are performed in parallel, it is possible to decrease the number of times of length measurement for deciding the focal point of the exposure light. Accordingly, the manufacturing method of the liquid crystal display panel according to the embodiment 3 can suppress power consumption of a direct exposure machine, for example.

Further, in the manufacturing method of a liquid crystal display panel according to the embodiment 3, for example, it is not always necessary to use the region constituted of two or more small regions EA arranged continuously in the x direction as the length measurement unit region in all belt-like regions CA. That is, in the manufacturing method of a liquid crystal display panel according to the embodiment 3, for example, the length measurement unit region at a portion where lines such as the scanning signal lines 3 are formed densely in the same manner as the inside of the circuit forming region BA may have the same size as one small region EA, and only the length measurement unit region at a portion where lines are not formed in the same manner as the separation region may be formed of the region constituted of two or more small regions EA arranged continuously in the x direction.

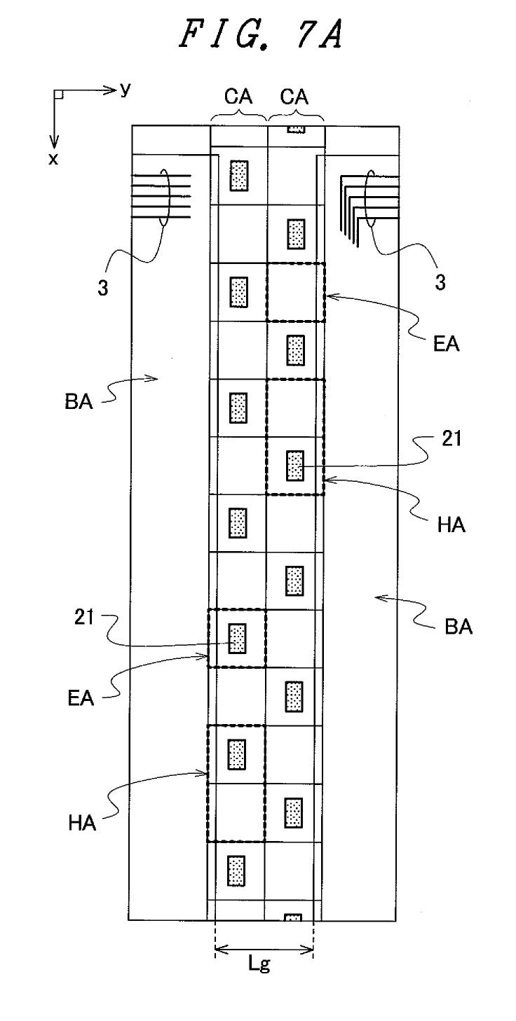

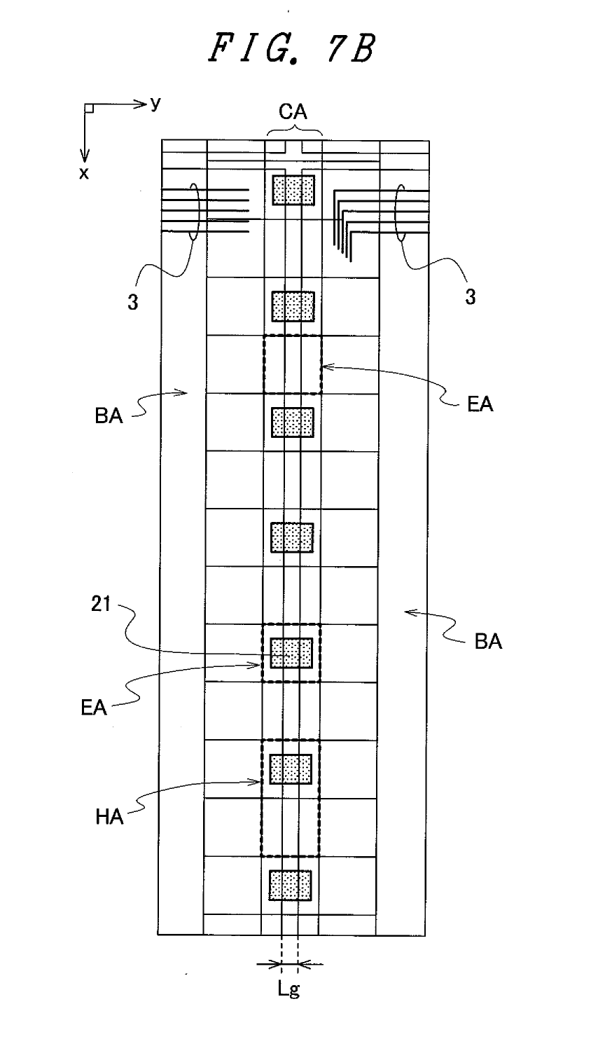

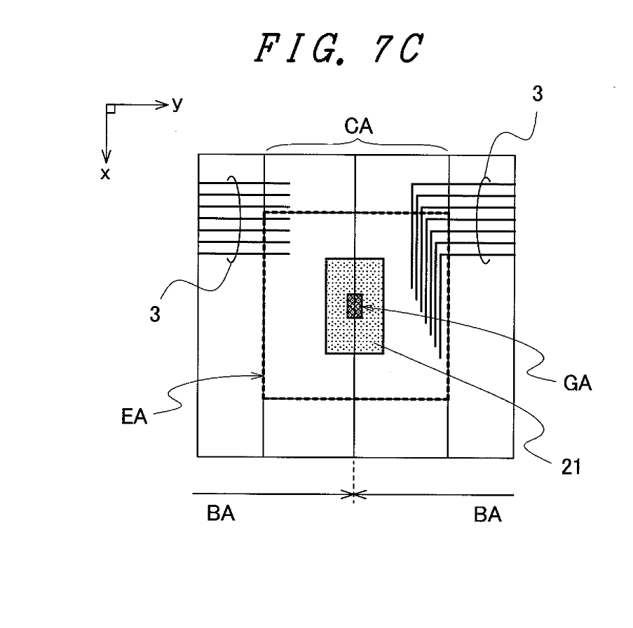

FIG. 7A to FIG. 7C are schematic views for explaining modifications of the manufacturing method of a liquid crystal display panel according to the embodiment 3.

FIG. 7A is a schematic view showing a first modification of the manufacturing method of a liquid crystal display panel according to the embodiment 3. FIG. 7B is a schematic view showing a second modification of the manufacturing method of a liquid crystal display panel according to the embodiment 3. FIG. 7C is a schematic view showing a third modification of the manufacturing method of a liquid crystal display panel according to the embodiment 3.

In the manufacturing method of a liquid crystal display panel, a width of the separation region which separates two neighboring circuit forming regions BA from each other on the mother glass 11 differs corresponding to a size of the mother glass 11, a size of the circuit forming regions BA or the like.

Accordingly, in the manufacturing method of a liquid crystal display panel by multiple-piece collective manufacturing, for example, as shown in FIG. 7A, there may be a case where a width (size in the y direction) Lg of the separation region becomes larger than the size Ly of the belt-like region CA (small region EA) in the y direction.

In such a case, in the small region EA which belongs to the belt-like region CA, the scanning signal lines 3, the video signal lines and the like are not formed. Accordingly, to decide a focal point of the exposure light to be radiated to the small region EA in exposing the photosensitive material film 19 formed on the transparent conductive film 18, it is desirable to form the light reflection layer 21 in each small region EA before the formation of the transparent conductive film 18.

However, in the manufacturing method of a liquid crystal display panel according to the embodiment 3, for example, as shown in FIG. 6B, one length measurement unit region HA is constituted of two small regions EA arranged adjacent to each other in the x direction. Accordingly, in forming the light reflection layer 21 by adopting the manufacturing method of a liquid crystal display panel according to the embodiment 3, as shown in FIG. 7A, two small regions EA arranged adjacent to each other in the longitudinal direction (x direction) of the belt-like region CA are regarded as one length measurement unit region HA, and the light reflection layers 21 are formed in a scattered manner like dots at a rate of one light reflection layer 21 in one length measurement unit region HA.

Further, in the example shown in FIG. 7A, the light reflection layer 21 is arranged in one small region out of two small regions EA arranged adjacent to each other in the x direction, and the light reflection layer 21 is arranged in one small region out of two small regions EA arranged adjacent to each other in the y direction. Due to such arrangement, a focal point of exposure light to be radiated to the small region EA where the light reflection layer 21 is not present can be decided based on a result of measurement of the distance from the optical system 20 to the photosensitive material film 19 in a small region above the small region EA, a small region below the small region EA and a small region on a right side or a left side of the small region EA.

The arrangement method of the light reflection layers 21 when the width Lg of the separation region is larger than the size Ly of the belt-like region CA (small region EA) in the y direction is not limited to the above-mentioned arrangement method. For example, it is needless to say that a set in which the light reflection layer 21 is arranged in both of two small regions EA arranged adjacent to each other in the y direction and a set in which the light reflection layer 21 is arranged in neither of two small regions EA arranged adjacent to each other in the y direction are alternately aligned in the x direction.

Further, in the example shown in FIG. 7A, one length measurement unit region HA is constituted of two small regions EA arranged adjacent to each other in the x direction. However, it is needless to say that the formation of the length measurement unit region HA is not limited to such an example, and one length measurement unit region HA may be constituted of three or more small regions EA which are arranged continuously in the x direction.

Further, in the manufacturing method of a liquid crystal display panel by multiple-piece collective manufacturing, for example, as shown in FIG. 7B, there may be a case where the width Lg of the separation region is extremely small compared to the size Ly of the belt-like region CA (small region EA) in the y direction. In this case, portions of the light reflection layer 21 may project into the circuit forming regions BA as shown in FIG. 7B, for example.

When the portions of the light reflection layer 21 project into the circuit forming region BA, it is desirable that the light reflection layer 21 does not come into contact (interfere) with the scanning signal lines 3 or the like.

Further, in the manufacturing method of a liquid crystal display panel by multiple-piece collective manufacturing, a plurality of liquid crystal panes manufactured by using a pair of mother glasses are divided into individual liquid crystal display panels by cutting. Here, for example, when the light reflection layer 21 formed of an opaque metal film is provided on the whole outer periphery of the circuit forming region BA on the mother glasses 11, in cutting the mother glasses 11, it is also necessary to cut the light reflection layer 21. Accordingly, there may be a case where a cut surface becomes a rough surface or an insulation layer formed on the first substrate 1 is peeled off in the obtained liquid crystal display panel, for example.

To the contrary, when the light reflection layers 21 are provided in a scattered manner like dots on the outer periphery of the circuit forming region BA as shown in FIG. 7B, an amount of light reflection layers 21 to be cut is small. Accordingly, the arrangement method of the light reflection layers shown in FIG. 7B is advantageous for preventing a cut surface of the liquid crystal display panel from becoming rough or for preventing the insulation layer formed on the first substrate 1 from being peeled off.

Further, in the manufacturing method of a liquid crystal display panel by multiple-piece collective manufacturing, for example, as shown in FIG. 7C, there may be a case where the width Lg of the separation region is approximately 0, and an opaque metal layer such as the scanning signal line 3 is formed in the small region EA where the separation region (separation line) passes.

However, in such a case, lines necessary for an operation of a liquid crystal display panel such as the scanning signal lines 3 are formed away from the separation region (separation line) by a predetermined distance. Accordingly, in the periphery of the representative region GA, an opaque metal layer is not usually present. Accordingly, when there are no lines formed of an opaque metal film in the representative region GA, as shown in FIG. 7C, the light reflection layer 21 is formed in such a region so that the distance from the optical system 20 to the photosensitive material film 19 can be accurately measured (calculated).

Although the present invention has been specifically explained in conjunction with the embodiments heretofore, it is needless to say that the present invention is not limited to the above-mentioned embodiments, and various modifications are conceivable without departing from the gist of the present invention.

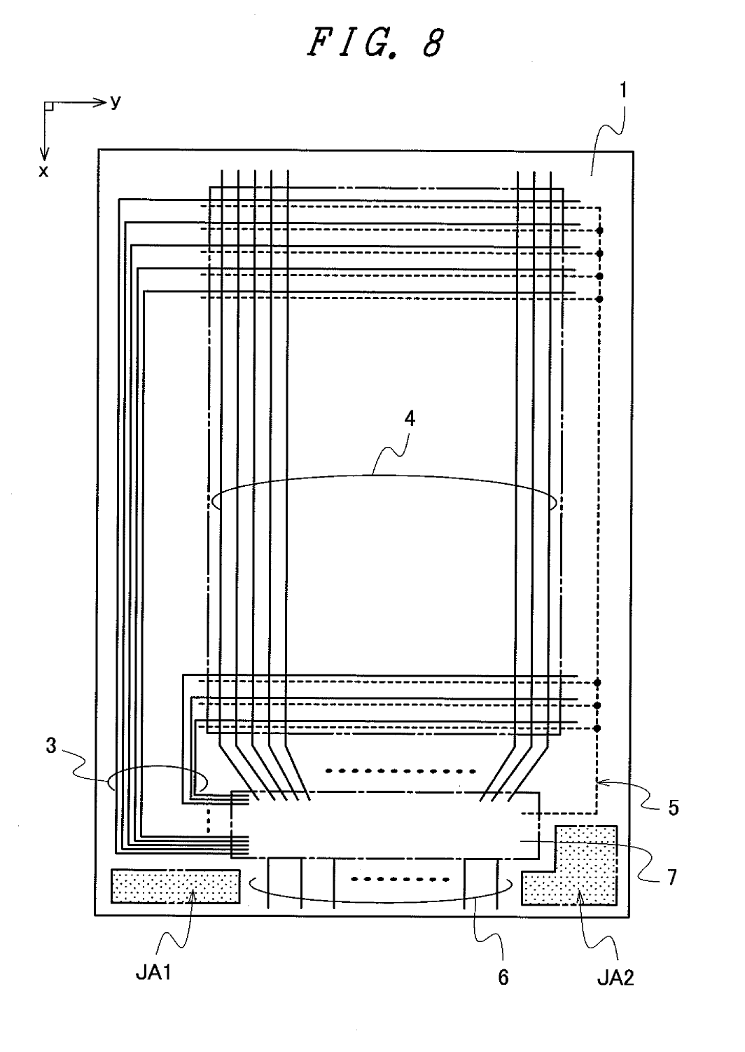

FIG. 8 is a schematic view for explaining an application example of the manufacturing method of a display device of the present invention.

In the above-mentioned embodiments, the explanation has been made with respect to the case where the liquid crystal display panel is manufactured by multiple-piece collective manufacturing as an example, wherein the light reflection layer 21 is formed outside or in the vicinity of the outer periphery of the circuit forming regions BA so as to form the separation region which separates two neighboring circuit forming regions BA from each other.

However, in forming lines such as the scanning signal lines 3 in the circuit forming regions BA (first substrate 1), for example, as shown in FIG. 8, regions JA1, JA2 where lines are not formed may exist. Here, when an area of the region JA1, JA2 is several times or several ten times larger than an area of the small region EA, for example, in the same manner as the small region which exists within the separation region, a focal point of exposure light to be radiated to the small region EA in the region JA1, JA2 cannot be decided.

Accordingly, when the area of the region JA1, JA2 which falls within the circuit forming region BA and in which the lines are not formed is large, the light reflection layer 21 may be formed in the region JA1, JA2.

Further, in this specification, as one example of the liquid crystal display panel manufactured by multiple-piece collective manufacturing, for example, as shown in FIG. 1A, the liquid crystal display panel used in the liquid crystal display of a portable electronic apparatus such as a mobile phone terminal is named. However, the manufacturing method of a display device according to the present invention is not limited to such a miniaturized liquid crystal display panel in which a diagonal size of a display region DA is approximately several inches. For example, it is needless to say that the manufacturing method of a display device according to the present invention is also applicable to a case where a liquid crystal display panel in which a diagonal size of the display region DA is approximately ten and several inches to several ten inches is manufactured by multiple-piece collective manufacturing.

Further, in this specification, as one example of the manufacturing method of a liquid crystal display panel by multiple-piece collective manufacturing, for example, as shown in FIG. 2, the explanation has been made with respect to the case where 192 pieces of liquid crystal display panels are collectively manufactured using the pair of mother glasses. However, the manufacturing method of a display device according to the present invention is not limited to such a case. For example, it is needless to say that the manufacturing method of a display device according to the present invention is applicable to a case where approximately several to ten and several liquid crystal display panels are collectively manufactured using a pair of mother glasses or a case where a further larger number of liquid crystal display panels are collectively manufactured using a pair of mother glasses.

Further, the manufacturing method of a display device according to the present invention is not limited to multiple-piece collective manufacturing. It is needless to say that the manufacturing method of a display device according to the present invention is also applicable to a case where one piece of liquid crystal display panel is manufactured using a pair of mother glasses.

Further, in this specification, the manufacturing method of a liquid crystal display panel has been explained as one example of the manufacturing method of a display device according to the present invention. However, the manufacturing method of a display device according to the present invention is not limited to such a manufacturing method. That is, it is needless to say that the manufacturing method of a display device according to the present invention is applicable to a manufacturing method of another display panel having a step in which a photosensitive material film formed on a light-transmitting film is exposed. For example, the manufacturing method of a display device according to the present invention is also applicable to manufacturing method of self-luminous display panel which uses an organic EL material or the like.

What is claimed is:

1. A manufacturing method of a display device comprising the steps of:
forming a light-transmitting film on a substrate;
forming a photosensitive material film on the light-transmitting film;
exposing the photosensitive material film using an exposure device; and
developing the exposed photosensitive material film, wherein
the step of exposing the photosensitive material film includes: a first step in which a whole exposure subject region of the photosensitive material film is divided into a plurality of small regions, and a focal point of light to be radiated to the small region is decided for every small region; and a second step in which respective small regions are sequentially exposed while setting focal points of lights to be radiated to the respective small regions to the focal points decided in the first step, wherein
in the first step, the whole exposure subject region of the photosensitive material film is divided into a plurality of belt-like regions which extend in the same longitudinal direction, each belt-like region is divided into a plurality of length measurement unit regions arranged parallel to each other in the longitudinal direction, a distance from an optical system of the exposure device to the photosensitive material film is calculated for each length measurement unit region, and the focal point of light to be radiated to each small region is decided based on the calculated distance, and
an opaque conductive layer is formed on said each length measurement unit region before the step of forming the light-transmitting film.

2. The manufacturing method of a display device according to claim 1, wherein the length measurement unit region has the same size as the small region.

3. The manufacturing method of a display device according to claim 1, wherein the small region is a quadrangular region which is surrounded by sides of the belt-like region extending in the longitudinal direction and sides of the belt-like region extending in the lateral direction, and in the length measurement unit region, a size of the belt-like region in the lateral direction is equal to a size of a small region in the lateral direction, and a size of the belt-like region in the longitudinal direction is two times or more larger than the size of the small region in the longitudinal direction.

4. The manufacturing method of a display device according to claim 1, wherein the small region is a quadrangular region which is surrounded by sides of the belt-like region extending in the longitudinal direction and sides extending in the lateral direction, and sets a size thereof in the lateral direction equal to a size of the belt-like region in the lateral direction, and the plurality of belt-like regions include the belt-like regions each of which is divided into the length measurement unit regions where the size of the belt-like region in the longitudinal direction is equal to the size of the small region, and the belt-like regions each of which is divided into the length measurement unit regions where the size of the belt-like region in the longitudinal direction is two times or more larger than the size of the small region.

5. The manufacturing method of a display device according to claim 1, wherein the first step and the second step are performed in parallel, and the respective small regions arranged parallel to each other in the longitudinal direction of the belt-like region are sequentially exposed in the second step.

6. A manufacturing method of a display device in which a plurality of circuit forming regions are formed on one sheet of substrate, and a circuit including a plurality of scanning signal lines, a plurality of video signal lines, a plurality of TFT elements and a plurality of transparent electrodes are formed on each circuit forming region, wherein
a separation region which separates two neighboring circuit forming regions from each other is provided between said two neighboring circuit forming regions, and
in forming the scanning signal lines in said each circuit forming region, a conductive layer which is not electrically connected with the scanning signal lines is formed in the separation region simultaneously with the scanning signal lines.

7. A manufacturing method of a display device in which a plurality of circuit forming regions are formed on one sheet of substrate, and a circuit including a plurality of scanning signal lines, a plurality of video signal lines, a plurality of TFT elements and a plurality of transparent electrodes are formed on each circuit forming region, wherein
a separation region which separates two neighboring circuit forming regions from each other is provided between said two neighboring circuit forming regions, and
in forming the video signal lines in said each circuit forming region, a conductive layer which is not electrically connected with the video signal lines is formed in the separation region simultaneously with the video signal lines.

8. The manufacturing method of a display device according to claim 7, wherein the conductive layer has a grid-like planar shape.

9. The manufacturing method of a display device according to claim 7, wherein the conductive layer is formed independently for every separation region.

10. The manufacturing method of a display device according to claim 7, wherein the plurality of circuit forming regions are arranged in a matrix array in the first direction and the second direction, and
the conductive layer is formed only in the separation regions each of which separates said two circuit forming regions arranged adjacent to each other in the first direction out of the separation regions.

11. The manufacturing method of a display device according to claim 7, wherein the transparent electrode is an electrode which is connected to a source or a drain of the TFT element, and the scanning signal lines and the video signal lines are formed prior to the formation of the transparent electrodes.

12. The manufacturing method of a display device according to claim 6 or claim 7, wherein the transparent electrodes include first transparent electrodes each of which is connected to a source or a drain of the TFT element, and second transparent electrodes which are arranged between the substrate and the first transparent electrodes, and the scanning signal lines and the video signal lines are formed prior to the formation of the first transparent electrodes.

13. The manufacturing method of a display device according to claim 12, wherein the scanning signal lines and the video signal lines are formed prior to the formation of the second transparent electrodes.

14. A display device having a display panel which arranges a plurality of lines, a plurality of TFT elements and a plurality of transparent electrodes on an insulation substrate, wherein
an opaque conductive layer which is electrically connected with none of the lines, the TFT elements and the transparent electrodes is arranged on an outer peripheral portion of the insulation substrate.

15. The display device according to claim 14, wherein the display panel is a liquid crystal display panel.
